(19) United States
(12) Patent Application Publication
(10) Pub. No.: US 2017/0221747 A1
(43) Pub. Date: Aug. 3, 2017

(54) PIN STRUCTURE, METHOD FOR OPERATING THE SAME, AND SUPPORTING DEVICE CONTAINING THE SAME

(71) Applicants: BOE TECHNOLOGY GROUP CO., LTD, Beijing (CN); BEIJING BOE DISPLAY TECHNOLOGY CO., LTD., Beijing (CN)

(72) Inventors: Yang HUANG, Beijing (CN); Liquan CUI, Beijing (CN); Lin LI, Beijing (CN)

(73) Assignees: BOE TECHNOLOGY GROUP CO., LTD, Beijing (CN); BEIJING BOE DISPLAY TECHNOLOGY CO., LTD., Beijing (CN)

(21) Appl. No.: 15/500,968

(22) PCT Filed: May 20, 2016
(86) PCT No.: PCT/CN2016/082887

§ 371 Date: Feb. 1, 2017

(30) Foreign Application Priority Data
Aug. 21, 2015 (CN) 201510519811.7

(51) Int. Cl. H01L 21/687

(52) U.S. Cl. CPC H01L 21/6875; H01L 21/68742; H01L 21/68792

(57) ABSTRACT

The present disclosure provides a pin structure for providing support to a substrate. The pin structure includes a first supporting unit and a second supporting unit over the first supporting unit. The first supporting unit includes at least one first supporting pin, each supporting pin being insertable through a pin hole of a lower panel; and the second supporting unit includes at least two second supporting pins for supporting a substrate.

### CROSS-REFERENCES TO RELATED APPLICATIONS

This PCT patent application claims priority of Chinese Patent Application No. 201510519811.7, filed on Aug. 21, 2015, the entire content of which is incorporated by reference herein.

### TECHNICAL FIELD

The present invention generally relates to the display technologies and, more particularly, relates to a pin structure, a method for using the same, and a supporting device containing the same.

### BACKGROUND

In semiconductor fabrication, a plurality of pin structures is often disposed on a holder to support wafers or substrates. For example, as shown in FIG. 1, an existing pin structure often includes a pin 1 and a driving module 4. The driving module 4 is often configured to drive the pin 1 to move upwardly and downwardly along the vertical direction. When the pins 1 arrive at a desired position, a substrate 3 is placed on the pins 1. Thus, the pins 1 of a plurality of pin structures can be used to support the substrate 3.

When an existing pin structure is supporting a substrate 3, the pressed areas on the substrate 3, i.e., area contacting and being pressed by the pins 1, are small. That is, the pressed areas only include a plurality of contacting points between the plurality of pins 1 and the substrate 3. It should be noted that, under gravity, the substrate 3 may undergo deformation. If the deformation causes the substrate 3 to completely attach and conform to a lower panel, subsequent fabrication processes, e.g., a heating process, may cause non-uniform process on the substrate 3. The processed substrate 3 may have impaired properties/functions.

Thus, a plurality of auxiliary supporting pins 2 are often disposed on the lower panel to provide auxiliary and supplementary support to the substrate 3, so as to avoid the bottom of the substrate 3 to attach onto the lower panel. Alternatively, the lower panel may also be roughened to avoid generating non-gap between the substrate 3 and the lower panel when they are in contact with each other.

However, the existing pin structure has some issues.

First, using the auxiliary supporting pins 2 and roughening the lower panel may prevent the substrate 3 from contacting the lower panel, but the substrate 3 may still undergo some deformation. Fabrication of the substrate 3 may be adversely affected.

Second, if using the auxiliary supporting pins 2 to provide complementary support to the substrate 3, it can be difficult to replace the auxiliary supporting pins 2. If the lower panel is roughened to avoid contact or conformal attachment between the lower panel and the substrate 3, friction may occur between the lower panel and the substrate 3, which may damage the substrate 3. Meanwhile, roughening the lower panel may also mirrorize the lower panel. As a result, it may be difficult to ensure gaps generated between the lower panel and the substrate 3 when they are in contact with each other. The fabrication of the substrate 3 may be adversely affected.

### BRIEF SUMMARY

The present disclosure provides a pin structure and a supporting device containing the pin structure. The disclosed pin structure may reduce the deformation of the substrate so that the substrate has no contact with the lower panel. The fabrication of the substrate can be improved. Meanwhile, the replacement of upper supporting pins is easier.

One aspect of the present disclosure includes a pin structure for providing support to a substrate. The pin structure includes a first supporting unit and a second supporting unit over the first supporting unit. The first supporting unit includes at least one first supporting pin, each supporting pin being insertable through a pin hole of a lower panel. The second supporting unit includes at least two second supporting pins for supporting a substrate.

Optionally, the first supporting unit is connected to the second supporting unit through a connecting structure.

Optionally, the first supporting unit includes one first supporting pin, a top portion of a first supporting pin being connected to the connecting structure through fixed connections, and the at least two second supporting pins being fixed onto the connecting structure.

Optionally, a distance between a first location and a second location is between about 15 mm to about 35 mm, the first location being a location on the connecting structure for connecting with a second supporting pin and the second location being a geometric center of first locations.

Optionally, the at least two second supporting pins are distributed along a perimeter of one or more circles, each circle centering about the second location.

Optionally, a second supporting pin is symmetrically configured with another second supporting pin, and the at least two second supporting pins geometrically center about the first supporting pin at the second location.

Optionally, the first supporting unit is connected to the second supporting unit directly, and the first supporting unit includes one first supporting pin.

Optionally, a second supporting pin includes a first supporting portion and a second supporting portion over the first supporting portion, the second supporting portion contacting the substrate and being made of an insulating material.

Optionally, the second supporting portion has a hat shape over a corresponding first supporting portion.

Optionally, a second supporting pin is made of an insulating material.

Optionally, the insulating material is resin.

Optionally, the pin structure further includes a driving module flexibly connected with the first supporting unit to drive the first supporting unit to move upwardly and downwardly along a vertical direction.

Optionally, the driving module is a cylinder.

Optionally, a top portion of each second supporting pins are located in a same horizontal plane.

Another aspect of the present disclosure provides a supporting device. The supporting device includes one or more of the disclosed pin structures.

Optionally, the supporting device further includes a lower panel with a plurality of trenches, dimensions of each trench matching dimensions of a corresponding second supporting unit such that at least a portion of the corresponding second supporting unit slides into the trench to contact the lower panel.

Optionally, the lower panel further includes a plurality of pin holes, at least one pin hole being located in a trench and having a size matching a corresponding first supporting pin such that a corresponding first supporting pin slides through the pin hole to be flexibly connected to the driving module.

Another aspect of the present disclosure provides a method for using the disclosed pin structure. According to the method, when one or more of the second supporting pins in a second supporting unit require to be replaced, the corresponding pin structure is replaced.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates an existing pin structure;

FIG. 2 illustrates an exemplary pin structure according to various embodiments of the present disclosure;

FIG. 3 illustrates an exemplary supporting device according to various embodiments of the present disclosure;

FIG. 4 illustrates another exemplary supporting device according to various embodiments of the present disclosure;

FIG. 5 illustrates a top view of an exemplary pin structure according to various embodiments of the present disclosure;

FIG. 6 illustrates another exemplary pin structure according to various embodiments of the present disclosure;

FIG. 7 illustrates another exemplary pin structure according to various embodiments of the present disclosure:

FIG. 8 illustrates another exemplary pin structure according to various embodiments of the present disclosure; and

FIG. 9 illustrates a cross-sectional view of an exemplary upper supporting pin according to various embodiments of the present disclosure.

### DETAILED DESCRIPTION

For those skilled in the art to better understand the technical solution of the invention, reference will now be made in detail to exemplary embodiments of the invention, which are illustrated in the accompanying drawings. Wherever possible, the same reference numbers will be used throughout the drawings to refer to the same or like parts.

According to the pin structure provided by the present disclosure, an upper supporting unit may include at least two upper supporting pins. Each upper supporting pin may function as a supporting point to the substrate. That is, each supporting device may include at least two supporting points. When the same number of pin structures is used in a fabrication process of the substrate, the disclosed pin structures may provide more supporting points to the substrate than existing pin structures. The substrate may be less susceptible to deformation and may not contact the lower panel. Thus, in the present disclosure, no additional auxiliary supporting pins or roughening the lower panel are needed. The lower panel would not be mirrorized. Meanwhile, when the disclosed upper supporting pins needs to be replaced, the corresponding pin structures may be replaced directly. The replacement of the upper supporting pins or the pin structures may be more convenient and faster. In addition, because the substrate is less susceptible to deformation, the substrate may have a flatter surface for further process. Better fabrication process of the substrate may be realized.

One aspect of the present disclosure provides a pin structure. The pin structure may be used for providing support to a substrate. The pin structure may include a first supporting unit and a second supporting unit over the first supporting unit. The first supporting unit includes at least one first supporting pin, each supporting pin being inserted through a pin hole of a lower panel. The second supporting unit includes at least two second supporting pins for supporting a substrate. A first supporting unit may be a lower supporting unit and a second supporting unit may be an upper supporting unit over the first supporting unit. A first supporting pin may be a lower supporting pin and a second supporting pin may be an upper supporting pin.

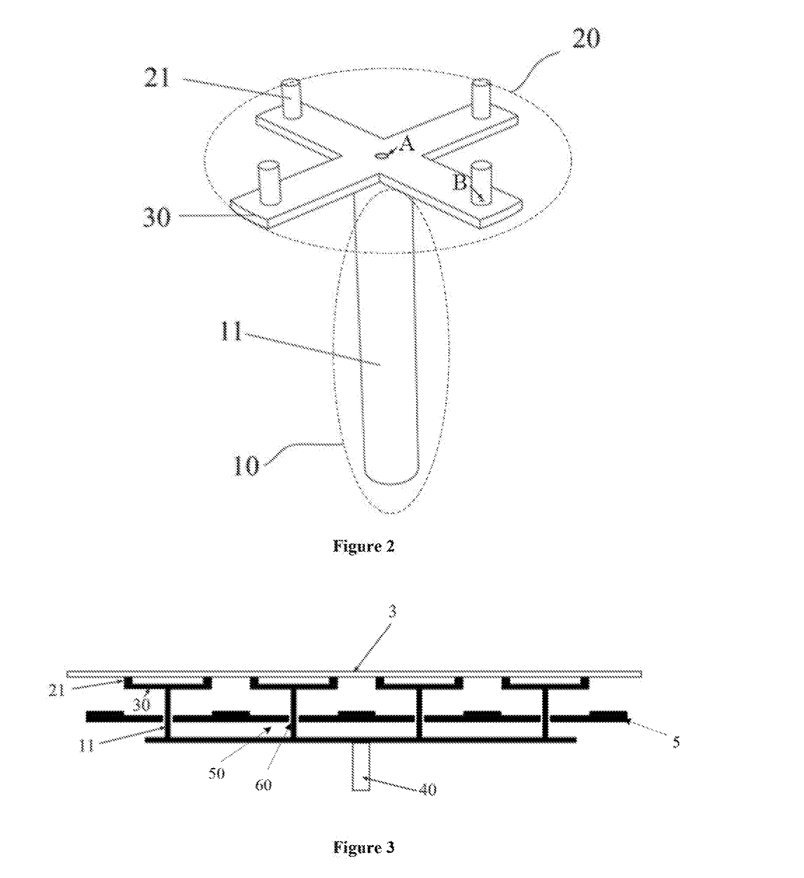

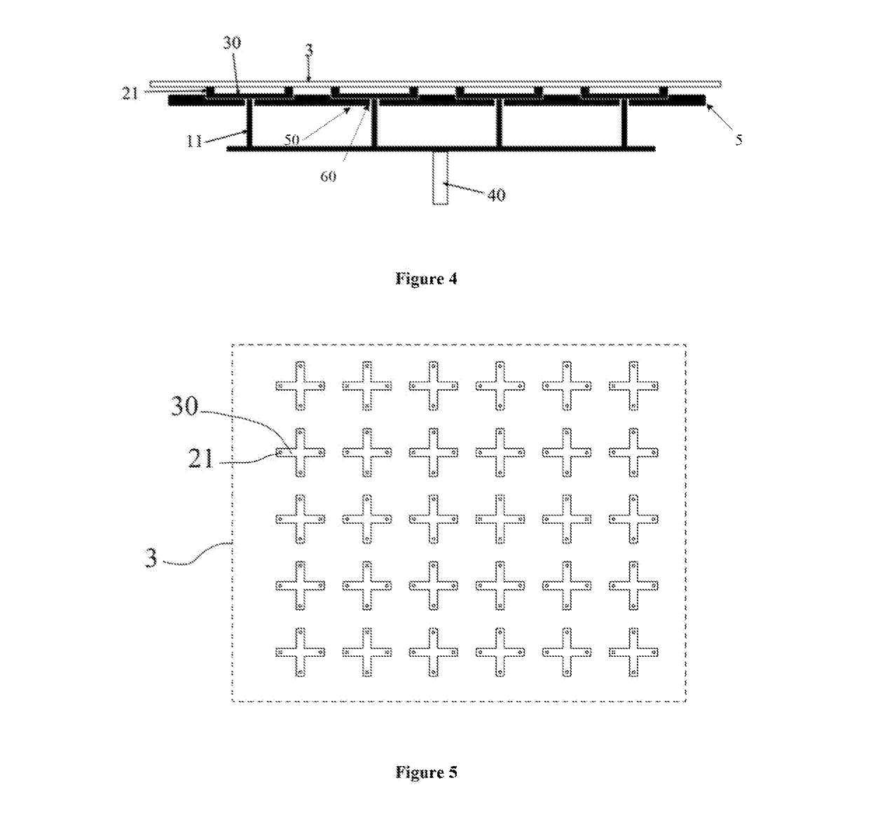

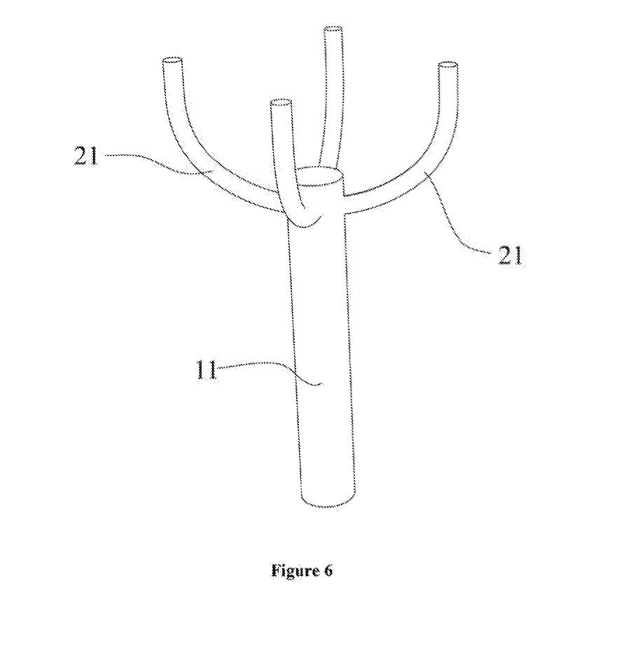

FIG. 2 illustrates an exemplary pin structure provided by the present disclosure. FIG. 3 illustrates a plurality of disclosed pin structures inserted or insertable in a lower panel and having flexible connections with a driving module. FIG. 4 illustrates an exemplary operation of the plurality of pin structures shown in FIG. 3. FIG. 5 illustrates the top view of a plurality of pin structures arranged in an array. FIGS. 6-8 illustrate other exemplary pin structure provided by the present disclosure. FIG. 9 illustrates the cross-sectional view of an exemplary upper supporting pin.

As shown in FIG. 2, the pin structure may include a lower supporting unit 10 and an upper supporting unit 20. The lower supporting unit 10 may be connected to the upper supporting unit 20. The lower supporting unit 10 may include at least one lower supporting pin 11. A lower supporting pin 11 is often disposed vertically through a lower panel 5, as shown in FIG. 3. A lower supporting pin 11 may slide or be inserted in and out a pin hole 60 in the lower panel. The upper supporting unit 20 may include a plurality of upper supporting pins 21. The number of the upper supporting pins 21 may be at least two. In one embodiment, the number of the upper supporting pins 21 in the upper supporting unit 20 may be greater than the number of lower supporting pins 11 in the lower supporting unit 10. In the present disclosure, a lower supporting unit may be referred as a first supporting unit, and an upper supporting unit may be referred as a second supporting unit. A lower supporting pin may be referred as a first supporting pin, and an upper supporting pin may be referred as a second supporting pin.

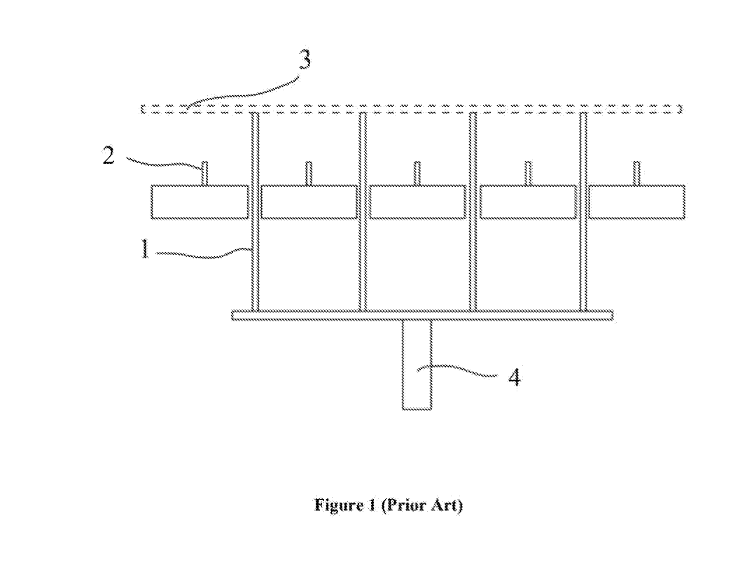

In one embodiment, the upper supporting unit 20 may include at least two upper supporting pins 21. Each upper supporting pin 21 may be used as a supporting point for supporting a substrate or a wafer. Thus, each pin structure may include a plurality of supporting points. Compared to an existing pin structure having one pin point, e.g., shown in FIG. 1, more supporting points (also referred to pin points) may be provided by each pin structure to contact and support the substrate 3 according to the present disclosure. For example, FIG. 3 shows a plurality of the disclosed pin structures used to support a substrate 3. Each pin structure may provide a plurality of upper supporting pins 21. The lower supporting pins 11 of the plurality of pin structures may be inserted or insertable through a lower panel 5. Accordingly, the lower panel 5 may include a plurality of pin holes 60 for the lower supporting pins 11 of the pin structures to go through and be flexibly connected to a driving module 40. Each lower supporting pin 11 may be inserted through a pin hole 60 on the lower panel 5 and further be flexibly connected to the driving module 40. The size of a pin hole 60 may match the size of a corresponding lower supporting pin 11 so that each lower supporting pin 11 may be properly arranged along the vertical direction.

Thus, the disclosed pin structure, having a plurality of supporting points, may provide increased contact area for supporting. As a result, each supporting point may be subjected to less pressure or less force compared with a supporting point in a conventional pin structure. That is, less pressure or force may be applied on the substrate 3 in areas where the substrate 3 contacts the upper supporting pins 21. Meanwhile, because more supporting points are used to support the substrate 3, the distribution of the supporting points may be denser, and the substrate 3 may be less susceptible to deformation. Contact between the substrate 3 and the lower panel 5 may be avoided. Auxiliary supporting pins may thus be optional. In one embodiment, no auxiliary supporting pins are needed. The lower panel 5 would not need to be roughened to prevent direct contact with the substrate 3. Mirrorization of the lower panel 5 may be avoided. Meanwhile, because the pin structures are flexibly connected to the driving module 40, when the upper supporting pins 21 need to be replaced, the corresponding pin structures may be replaced directly. For example, when the upper supporting pins 21 of a pin structure need to be replaced, the pin structure may be taken out from the lower panel 5 by sliding the lower supporting pins 11 of the pin structure from the corresponding pin holes 60 in the lower panel. The pin structure may thus be disconnected from the driving module 40. That is, a plurality of upper supporting pins 21 may be replaced all at once. The replacement of the upper supporting pins 21 may be more convenient. In addition, because the substrate 3 is less susceptible to deformation, in fabrication, the surface of the substrate 3 may have improved flatness. The fabrication of the substrate 3 may be improved.

It should be noted that, in the disclosure, a “flexible connection”, “being flexibly connected”, or the like refer to a connection with the connected parts being able to move, slide, and/or be disconnected at the connecting location. A “fixed connection”, “being fixed”, or the like refer to a connection with the connected parts not being able to move, slide, and/or be disconnected at the connecting location.

In one embodiment, the distribution of the supporting points may be symmetric about the geometric center of the supporting points so that the upper supporting pins 21 may provide a more uniformed support to the substrate.

In the present disclosure, as shown in FIGS. 3-5, the pin structure may further include a driving module 40. The driving module 40 may be flexibly connected to the lower supporting unit 10 of a pin structure to drive the lower supporting unit 10 to move upwardly and downwardly along the vertical direction. Specifically, the driving module 40 may be a cylinder. Referring to FIG. 3, the driving module 40 may drive the pin structures to move to a higher position along the vertical direction so that the substrate 3 may be farther away from the lower panel 5. Referring to FIG. 4, the driving module 40 may drive the pin structures to move to a lower position so that the substrate 3 may be closer to the lower panel. It can be shown from FIG. 4 that, even when the driving module 40 drives the pin structures to move to a lowest position, i.e., the substrate 3 being closest to the lower panel 5, the substrate 3 and the lower panel 5 still would not have contact with each other. Thus, contact between the substrate 3 and the lower panel 5 may be avoided. Because the driving module 40 is flexibly connected to the pin structures, when the upper supporting pins 21 need to be replaced, the corresponding pin structures may be replaced directly.

In some embodiments, as shown in FIGS. 3 and 4, the lower panel may include a plurality of trenches 50. The dimensions of each trench 50 may match the dimensions of a corresponding upper supporting unit such that at least a portion of the corresponding upper supporting unit may slide into the trench 50 to contact the lower panel 5. At least one pin hole 60 may be formed in each trench 50 so that the lower supporting pins 11 of each pin structure may slide into the pin holes 60 to form flexible connection with the driving module 40. In this way, the substrate 3 would not contact the lower panel 5, and the operating of the pin structures may be more stable. For example, the positions of the pin structures may be more precisely controlled. In addition, the driving module 40 may drive the pin structures to move in a greater range. Even when the pin structures are moved to the closest position, the substrate 3 still would not contact the lower panel 5. For illustrative purposes, FIG. 4 only shows one pin hole 60 in each trench.

In FIG. 5, a plurality of pin structures may be arranged in a plurality of rows and a plurality of columns to provide support to the substrate 3. FIG. 5 shows a top view of the plurality of pin structures. For illustrative purposes, the substrate 3 is shown to be transparent, which is illustrated by the dashed box. It should be noted that, the distribution of pin structures shown in FIG. 5 is only exemplary. In practice, the distribution/arrangement of the pin structures may be determined or adjusted according to different applications and designs.

Referring to FIGS. 3-5, in practice, a plurality of pin structures may be used to support one substrate 3 together. In this case, the plurality of pin structures may share one driving module 40 to reduce cost.

Referring to FIG. 2, the lower supporting unit 10 may include one lower supporting pin 11. By using one lower supporting pin 11 in the lower supporting unit 10, the number of pin holes or through holes on the lower panel 5 may be reduced, where the pin holes are used for the lower supporting unit 10 to go through. Less pin holes formed in the lower panel may enable the fabrication of the substrate 3 to be more uniformed, and better fabrication of the substrate 3 may be realized. For example, when using the lower panel to heat up the substrate, the temperature at the pin holes on the lower panel may be significantly lower than the temperature at the areas without pin holes. By reducing the number of pin holes on the lower panel, the temperature on the lower panel may be more uniformed. Areas or parts with lower temperature may be avoided. The temperature across the lower panel may be more uniformed. The heating process on the substrate may be improved.

Referring to FIG. 2, the lower supporting unit 10 may be connected to the upper supporting unit 20 through a connecting portion 30. Specifically, the upper supporting pins 21 may be fixed onto the connecting portion 30 vertically. When the pin structure is supporting a substrate 3, the connecting portion 30 may be kept to be horizontal so that each upper supporting pin 21 may maintain to be aligned vertically. The top portion of each upper supporting pin 21 may be located in a same plane and may contact the substrate to provide support to the substrate 3. In one embodiment, the plane may be a horizontal plane.

Referring to FIG. 2, as an example, the upper supporting unit 20 may include four upper supporting pins 21. The connecting portion 30 may include four parts, each located under a supporting pin 21. Each of the four parts of the connecting portion 30 may have a fan-blade shape or a similar structure, and one upper supporting pin 21 may be disposed on each fan-blade-shaped part. By having the connecting portion 30 with the structure described above, it may be cheaper to fabricate the pin structure. Also, an upper supporting unit 20 may include four upper supporting pins 21, so that the disclosed pin structure may include more supporting points compared to an existing pin structure. Meanwhile, the structure of the disclosed pin structure would not be undesirably complicated.

Further, as shown in FIG. 2, a plurality of locations on the connecting portion 30, having connections with a plurality of upper supporting pins 21, may be the first locations. The location on the connecting portion 30, having connection with the lower supporting pin 11, may be the second location. As shown in FIG. 2, a first location may be labeled as point B, and the second location may be labeled as point A. In some embodiments, the first locations B may be located in a circle centered about the second location A. In one embodiment, a distance between a first location B and the second location A, e.g., the radius of the circle, may be about 15 mm to about 35 mm. The choice of the distance may enable the plurality of upper supporting pins 21 in each pin structure to provide support to the substrate in a desirably large range. Meanwhile, the arms of force of the connecting portion 30 would not be undesirably long such that damages to the connecting portion 30 may be avoided.

In one embodiment, the second location A may be the geometric center of the first locations B. For example, if the lower supporting unit 10 includes only one lower supporting pin 11, the lower supporting pin 11 may be connected to the supporting structure 30 at the second location A. That is, the first locations B may be distributed to be symmetric about the second location A. In certain embodiments, first locations B may be symmetrically distributed about the second location A.

In one embodiment, in the pin structure shown in FIG. 2, the top portion of the lower supporting pin 11 may also form flexible connections with the connecting portion 30. Thus, when the substrate is placed on the pin structure, even if the lower supporting pin 11 is inclined and not aligned vertically for any reason, e.g., being knocked down, the connecting portion 30 may still maintain to be aligned horizontally under external forces, e.g., the gravity of the substrate. That is, the plurality of upper supporting pins 21 of the upper supporting unit 20 may provide support to the substrate effectively. It should be noted that, in this case, only one lower supporting pin 11 is included in the lower supporting unit 10 for forming flexible connection with the connecting portion 30.

In one embodiment, the connecting portion 30 is optionally configured to connect the upper supporting unit 20 with the lower supporting unit 10. In other various embodiments of the present disclosure, the upper supporting unit 20 may also be disposed on the lower supporting unit 10 directly, as shown in FIG. 6. That is, a plurality of upper supporting pins 21 may be directly fixed onto the lower supporting pin 11. In this case, the lower supporting unit 10 may include only one lower supporting pin 11.

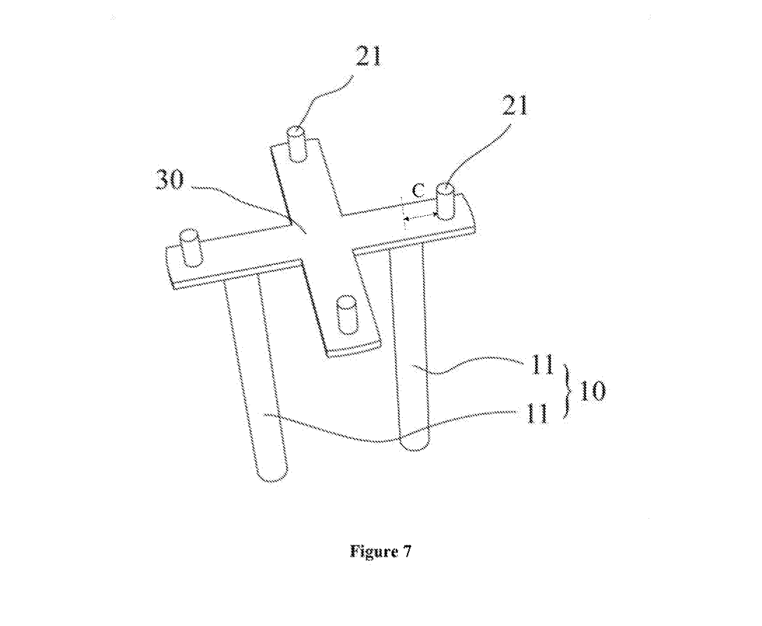

In some embodiments, only one lower supporting pin 11 is included in the lower supporting unit 10 as shown in FIG. 2. In other embodiments, the lower supporting unit 10 may include a plurality of lower supporting pins 11, as shown in FIG. 7.

In FIG. 7, the lower supporting unit 10 may be connected to the upper supporting unit 20 through the connecting portion 30. Specifically, the top portions of the plurality of the lower supporting pins 11 may be connected to the connecting portion 30, e.g., through fixed and vertical connections. The upper supporting pins 21 in the upper supporting unit 20 may be fixed on the connecting portion 30. In this case, the distance C between a first location and a corresponding second location, as shown in FIG. 7, may be determined according to different applications. For a pin structure shown in FIG. 7, the lower supporting pins 11 may form flexible connections with the driving module 40. When an upper supporting unit 20 needs to be replaced, the entire pin structure may be replaced. Details of the flexible connection and the replacement of pin structures may be referred to previous description and are not repeated herein.

In certain embodiments, for a pin structure shown in FIG. 7, the lower supporting pins 1 may also form flexible connections with the connection portion 30. That is, even if the lower supporting pins 11 are inclined and not aligned vertically for any reason, e.g., being knocked down, the connecting portion 30 may still maintain to be aligned horizontally under external forces, e.g., the gravity of the substrate 3. That is, the plurality of upper supporting pins 21 of the upper supporting unit 20 may provide support to the substrate effectively.

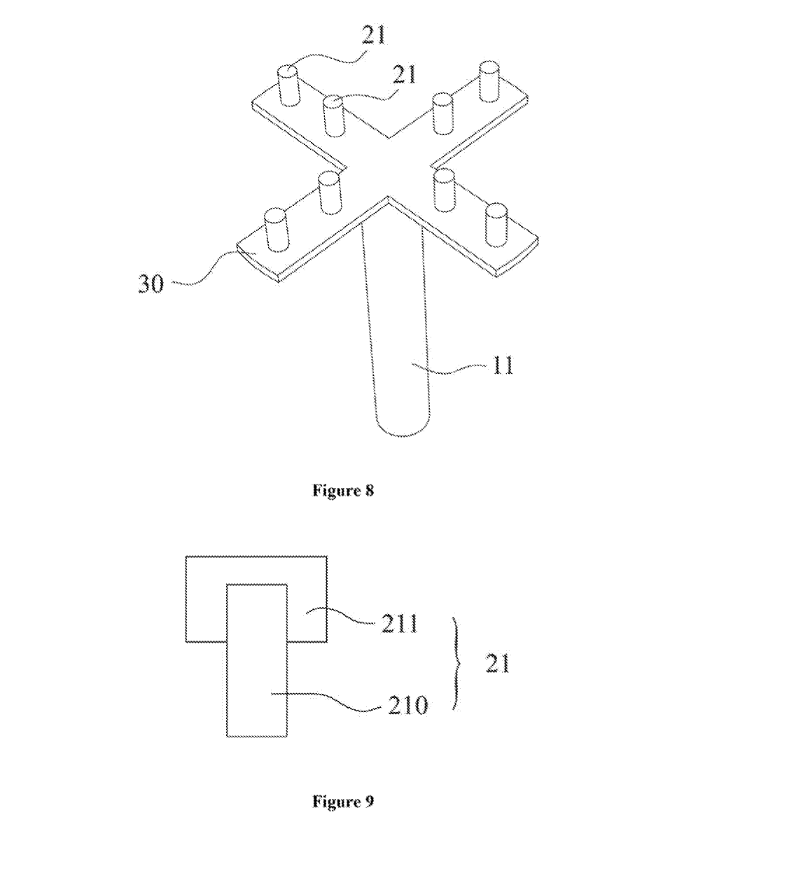

Referring to FIG. 2, the first locations B may be distributed along a perimeter of a circle, centered about the second position A. Also, the first locations B may be distributed in a plurality of circles centered by the second location A, as shown in FIG. 8. In this case, the circles centered about the second location A may have different radii. For example, a radius may range from about 15 mm to about 35 mm. The specific radius of each circle may be determined according to different applications so that a desirably uniformed support, by the upper supporting pins 21, may be provided to the substrate 3.

FIG. 9 illustrates a cross-sectional view of an exemplary upper supporting pin. As shown in FIG. 9, an upper supporting pin 21 may include a first supporting portion 210 and a second supporting portion 211 over the first supporting portion 210. The second supporting portion 211 may be made of a suitable insulating material. Thus, when a substrate is place on the pin structure, the second supporting portion 211 would not conduct electric charges upwardly to the substrate 3. Electrostatic charges between the second supporting portion 211 and the substrate 3 may be avoided. Fabrication of the substrate 3 may be improved. In one embodiment, the insulating material may be resin.

Further, the second supporting portion 211 may have a hat shape. The second supporting portion 211 may cover the top portion of the first supporting portion 210.

In certain embodiments, the first supporting portion 210 and the second supporting portion 211 of an upper supporting pin 21 may both be made of one or more suitable insulating materials, e.g., resin.

In the embodiments provided by the present disclosure, the upper supporting unit 20 may include a plurality of upper supporting pins 21. Each upper supporting pin 21 may function as a supporting point to the substrate. That is, each supporting device may include a plurality of supporting points. When the same number of pin structures is used in a fabrication process of the substrate, the disclosed pin structures may provide more supporting points to the substrate than existing pin structures. The substrate may be less susceptible to deformation and may not contact the lower panel. Thus, in the present disclosure, no additional auxiliary supporting pins or roughening the lower panel are needed. The lower panel would not be mirrorized. Meanwhile, when the disclosed upper supporting pins 21 needs to be replaced, the corresponding pin structures may be replaced directly. The replacement of the upper supporting pins 21 or the pin structures may be more convenient and faster. In addition, because the substrate is less susceptible to deformation, the substrate may have a flatter surface for further process. Better fabrication process of the substrate may be realized.

Another aspect of the present disclosure provides a supporting device. The supporting device may include one or more of the pin structures provided by the present disclosure.

The disclosed supporting device may include the pin structures provided by the present disclosure. The supporting device may include a lower panel with a plurality of trenches and a plurality of pin holes. The dimensions of a trench may match the dimensions of the corresponding upper supporting unit such that a least a portion of the upper supporting unit may slide into the trench. In this way, the substrate would not contact the lower panel, and the operating of the pin structures may be more stable. In addition, the driving module may drive the pin structures to move in a greater range. Even when the pin structures are moved to the closest position, the substrate still would not contact the lower panel. The size of each pin hole may match a corresponding lower supporting pin such that the corresponding lower supporting pins may slide through the pin hole to be flexibly connected to the driving module. Thus, the lower supporting unit of a pin structure may be properly arranged vertically.

By using the disclosed supporting device, the substrate may be less susceptible to deformation and may not contact the lower panel. Better fabrication process of the substrate may be realized. In addition, the pin structures may be replaced to more conveniently replace the corresponding upper supporting pins, which are used as the supporting points for the substrate.

Another aspect of the present disclosure provides a method for using the disclosed pin structure. The method comprises placing a substrate on the plurality of second supporting pins having pin points in the same horizontal plane to process the substrate.

In addition, according to the method, when one or more of the upper supporting pins in an upper supporting unit require replacement, the corresponding pin structures may be replaced.

It should be understood that the above embodiments disclosed herein are exemplary only and not limiting the scope of this disclosure. Without departing from the spirit and scope of this invention, other modifications, equivalents, or improvements to the disclosed embodiments are obvious to those skilled in the art and are intended to be encompassed within the scope of the present disclosure.

1-18. (canceled)

19. A pin structure for providing support to a substrate, comprising a first supporting unit and a second supporting unit over the first supporting unit, wherein:
the first supporting unit includes at least one first supporting pin, each supporting pin being insertable through a pin hole of a lower panel; and
the second supporting unit includes at least two second supporting pins for supporting a substrate.

20. The pin structure according to claim 19, wherein the first supporting unit is connected to the second supporting unit through a connecting structure.

21. The pin structure according to claim 20, wherein the first supporting unit includes one first supporting pin, a top portion of a first supporting pin being connected to the connecting structure through fixed connections, and the at least two second supporting pins being fixed onto the connecting structure.

22. The pin structure according to claim 21, wherein a distance between a first location and a second location is between about 15 mm to about 35 mm, the first location being a location on the connecting structure for connecting with a second supporting pin and the second location being a geometric center of first locations.

23. The pin structure according to claim 22, wherein the at least two second supporting pins are distributed along a perimeter of one or more circles, each circle centering about the second location.

24. The pin structure according to claim 22, wherein a second supporting pin is symmetrically configured with another second supporting pin, and the at least two second supporting pins geometrically center about the first supporting pin at the second location.

25. The pin substrate according to claim 19, wherein the first supporting unit is connected to the second supporting unit directly, and the first supporting unit includes one first supporting pin.

26. The pin substrate according to claim 19, wherein a second supporting pin includes a first supporting portion and a second supporting portion over the first supporting portion, the second supporting portion contacting the substrate and being made of an insulating material.

27. The pin substrate according to claim 26, wherein the second supporting portion has a hat shape over a corresponding first supporting portion.

28. The pin substrate according to claim 26, wherein a second supporting pin is made of an insulating material.

29. The pin substrate according to claim 26, wherein the insulating material is resin.

30. The pin structure according to claim 19, further including a driving module flexibly connected with the first supporting unit to drive the first supporting unit to move upwardly and downwardly along a vertical direction.

31. The pin structure according to claim 30, wherein the driving module is a cylinder.

32. The pin structure according to claim 19, wherein a top portion of each second supporting pins are located in a same horizontal plane.

33. A supporting device, comprising one or more pin structures each according to claim 19.

34. The supporting device according to claim 33, further including a lower panel with a plurality of trenches, dimensions of each trench matching dimensions of a corresponding second supporting unit such that at least a portion of the corresponding second supporting unit slides into the trench to contact the lower panel.

35. The supporting device according to claim 34, wherein the lower panel further includes a plurality of pin holes, at least one pin hole being located in a trench and having a size matching a corresponding first supporting pin such that a corresponding first supporting pin slides through the pin hole to be flexibly connected to the driving module.

36. A method for using the pin structure according to claim 19, comprising: when one or more of the second supporting pins in a second supporting unit require to be replaced, the corresponding pin structure is replaced.
